(19) United States
(12) Patent Application Publication
(10) Pub. No.: US 2025/0150032 A1
(43) Pub. Date: May 8, 2025

(54) Pairing of Components in a Direct Current Distributed Power Generation System

(71) Applicant: Solaredge Technologies Ltd., Herzeliya (IL)

(72) Inventors: Guy Sella, Bitan Aharon (IL); Meir Adest, Modiin (IL); Lior Handelsman, Givatayim (IL); Yoav Galin, Raanana (IL); Amir Fishelov, Tel Aviv (IL); Meir Gazit, Rosh Ha'ayin (IL); Ilan Yoscovich, Givatayim (IL); Yaron Binder, Shoham (IL)

(21) Appl. No.: 19/013,668

(22) Filed: Jan. 8, 2025

Related U.S. Application Data
(63) Continuation of application No. 18/338,527, filed on Jun. 21, 2023, now Pat. No. 12,224,706.
Application No. 18/338,527 is a continuation of application No. 17/398,840, filed on Aug. 10, 2021, now Pat. No. 11,728,768.
Application No. 17/398,840 is a continuation of application No. 15/949,369, filed on Apr. 10, 2018.
Application No. 15/949,369 is a continuation of application No. 14/743,018, filed on Jun. 18, 2015, now Pat. No. 9,960,731.
Application No. 14/743,018 is a continuation of application No. 13/015,612, filed on Jan. 28, 2011, now Pat. No. 9,112,379.

(51) Int. Cl. H02S 50/00; H02J 1/10; H02J 3/38; H02J 7/35; H02S 40/34; H10F 77/00

(52) U.S. Cl. CPC H02S 50/00; H02J 1/10; H02J 1/102; H02S 40/34; H10F 77/955; H02J 3/381; H02J 7/35; H02J 2300/24; Y02E 10/56; Y02E 10/76

(57) ABSTRACT

A method of signaling between a photovoltaic module and an inverter module. The inverter module is connected to the photovoltaic module. In an initial mode of operation an initial code is modulated thereby producing an initial signal. The initial signal is transmitted from the inverter module to the photovoltaic module. The initial signal is received by the photovoltaic module. The operating mode is then changed to a normal mode of power conversion, and during the normal mode of operation a control signal is transmitted from the inverter to the photovoltaic module. A control code is demodulated and received from the control signal. The control code is compared with the initial code producing a comparison. The control command of the control signal is validated as a valid control command from the inverter module with the control command only acted upon when the comparison is a positive comparison.

### CROSS-REFERENCE TO RELATED APPLICATIONS

This application is a continuation of U.S. application Ser. No. 18/338,527, filed Jun. 21, 2023, which is a continuation of U.S. application Ser. No. 17/398,840, filed Aug. 10, 2021, now U.S. Pat. No. 11,728,768, which is a continuation of U.S. application Ser. No. 15/949,369, filed Apr. 10, 2018, which is a continuation of U.S. application Ser. No. 14/743,018, filed Jun. 18, 2015, now U.S. Pat. No. 9,960,731, which is a continuation of U.S. application Ser. No. 13/015,612, filed Jan. 28, 2011, now U.S. Pat. No. 9,112,379. The entire disclosures of the foregoing applications are incorporated by reference in their entireties.

### FIELD AND BACKGROUND

### 1. Field

The present invention relates to power generation systems, and specifically to a system and method for reducing crosstalk while signaling between the components in direct current distributed power generation systems.

### 2. Related Art

A photovoltaic power generation system may incorporate one or more photovoltaic panels with optional electronic modules attached thereto. An inverter connects to the photovoltaic panels or electronic modules. Power output from the photovoltaic panels or electronic modules is direct current (DC) power. The electronic modules may perform direct current DC-to-DC conversion. The inverter inverts the DC power output to alternating current (AC) power.

As previously disclosed by the present inventors in US patent application publication 2008/0147335, the DC power cables connecting inverters to photovoltaic panels and/or electronic modules may provide a communication channel between the inverters and the photovoltaic panels or modules. The communication channel between inverters and modules, allows monitoring of the performance of the modules for monitoring temperature, current, voltage and power output of the photovoltaic modules and potentially allows for control of the modules.

Typically, lengths of cables connecting the inverter to the panels or modules may be long and may contain one or several wire cores. Within a photovoltaic installation, a wire at positive potential and a wire at negative potential electrically associated therewith may be physically proximate thereto only at a point of connection to a piece of equipment. However, elsewhere in the photovoltaic field, the wires may be separated and not be within the same cable run. The topography of the distributed power generation system to a large extent dictates the installation and placement of cable runs. Physical proximity of wires not having an electrical association may increase the chances of the wires in the cables being subject to the effects of noise if those wires are to be considered for signaling by DC power line communications. Crosstalk is a type of noise which refers to any phenomenon by which a signal transmitted on a cable, circuit or channel of a transmission system creates an undesired effect in another cable, circuit or channel. Crosstalk is usually caused by undesired capacitive, inductive, or conductive coupling from one cable, circuit or channel, to another. Crosstalk may also corrupt the data being transmitted. Typical known methods of preventing the undesirable effects of crosstalk may be to utilize the shielding of cables, modules, panels, inverters or using twisted pair cables. Additionally, filtering techniques such as matched filters, de-coupling capacitors or chokes may be used to prevent the undesirable effects of crosstalk. However, these typical ways of preventing the undesirable effects of crosstalk are typically unavailable or impractical for power line communications over DC lines in a power generation system and/or may be prohibitively expensive in terms of additional materials and/or components required.

In a photovoltaic power generation system, with power line communication over DC cables, it may be desirable to send a control signal between and an inverter and a particular photovoltaic module but no other modules. Crosstalk may cause the other photovoltaic modules in the power generation system to inadvertently receive the control signal which is of course undesirable.

Thus there is a need for and it would be advantageous to have a system and method of reducing cross-talk in DC power line communications in a distributed DC power generation system, e.g. photovoltaic DC power generation system.

The term “memory” as used herein refers to one or more of programmable read only memory (PROM), erasable programmable read only memory (EPROM), electrically erasable programmable read only memory (EEPROM), FLASH memory, optical memory, e.g. compact disk, switches, random access memory (RAM), magnetic memory such as a hard disk or other memory types known in the art.

The term “direct current (DC) power source” as used herein refers to (DC) power source such as batteries, DC motor generator; switch mode power supply (SMPS), photovoltaic panels and/or photovoltaic panels operatively attached to a converter module such as a DC to DC converter.

The term “photovoltaic source” as used herein refers to a photovoltaic panel and/or a photovoltaic panel operatively attached to a electronic module which includes for instance a DC-to-DC converter. The term “electronic module” and “photovoltaic module” are used herein interchangeably and refer to a functional electronic circuit attached to a photovoltaic panel.

The term “noise” as used herein in a communication channel, includes any unwanted signal finding itself in the communication channel. Sources of noise may include radio frequency interference (RPI), mains electricity hum, unsuppressed switching voltages and crosstalk.

The term “crosstalk” as used herein refers to any phenomenon by which a signal transmitted on a cable, circuit or channel of a transmission system creates an undesired effect in another cable, circuit or channel. Crosstalk is usually caused by undesired capacitive, inductive, or conductive coupling from one cable, a circuit, part of a circuit, or channel, to another.

The term “telemetry” as used herein refers to measurement, transmission and reception of data by wire, radio, or other means from remote sources. In the context of the present invention, telemetries are from the photovoltaic panels.

The term “transducer” as used herein refers to a device used for the conversion of one type of energy to another, for example, the device changes electrical energy in to electromagnetic energy and vice versa. The term “transducer” herein may also have functions of a sensor or detector. The terms “sensor” and “transducer” as used herein are used interchangeably.

The terms “signal”, “signaling” or “signaling mechanism” as used herein refers to a signal modulated on a carrier signal. The carrier signal may be an electrical or an electromagnetic signal. The signal may be a simple on/off signal or a complex signal which imparts information as data. For a modulated signal, the modulation method may be by any such method known in the art, by way of example, frequency modulation (FM) transmission, amplitude modulation (AM), FSK (frequency shift keying) modulation, PSK (phase shift keying) modulation, various QAM (quadrature amplitude modulation) constellations, or any other method of modulation. Although strictly, the terms “modulation” and “coding” are not equivalent, the term modulation and demodulation are typically used herein to include coding and decoding respectively.

The term “signal strength” as used herein refers to the magnitude of the electric field/current or voltage at a reference point that is a significant distance from a transmitting source. Typically, “signal strength” is expressed in voltage per length or signal power received by a reference point expressed in decibel (dB) per length (meter), dB-millivolts per meter (dBmV/m), and dB-microvolts per meter (dBp V/m) or in decibels above a reference level of one milliwatt (dBm).

The term “positive comparison” in reference to the comparison of two codes or two signals means equal within tolerances or thresholds or derivable one from the other in a known way.

### BRIEF SUMMARY

According to the present invention there is provided a method of signaling between a photovoltaic module and an inverter module. The inverter module is connected to the photovoltaic module. In an initial mode of operation an initial code is modulated to produce an initial signal. The initial signal is transmitted from the inverter module to the photovoltaic module. The initial signal is received by the photovoltaic module. The operating mode is then changed to a normal mode of power conversion, and during the normal mode of operation a control signal is transmitted from the inverter to the photovoltaic module. A control code is demodulated and received from the control signal. The control code is compared with the initial code producing a comparison. The control command of the control signal is validated as a valid control command from the inverter module with the control command only acted upon when the comparison is a positive comparison. Current output of photovoltaic modules may be limited during the initial mode of operation. The initial code is typically saved in a memory. Modulating the code may be performed by varying the input impedance of the inverter module to produce a variation in voltage or current at the output of the photovoltaic module. The photovoltaic module senses the variation in voltage or current at the output of the photovoltaic module. Respective signal strengths for the initial signal and the control signal may be measured. The signal strengths are compared to produce a comparison result. When the comparison result is greater than a previously stored threshold value then an alarm is set or the control command is invalidated. Fluctuations prior to measuring the signal strength are preferably filtered out. Electrical energy is typically stored for supplying power for the varying and the sensing.

According to the present invention there is provided a photovoltaic generation system with a photovoltaic module including a first transceiver connected to the DC power line. A load module is connected to the DC power line. The load module including a second transceiver is connected to the DC power line. There is a pairing mechanism and a signaling mechanism between the first and second transceivers. Based on the pairing mechanism, another photovoltaic module or another load module in the photovoltaic generation system is excluded from signaling with either the photovoltaic module or the load module. A charge storage device may be included within the photovoltaic module adapted to store charge and supply power to the photovoltaic module. A second photovoltaic module may be attached to the photovoltaic module along with a second signaling mechanism adapted to signal between the photovoltaic module and the second photovoltaic module. The signaling mechanism is typically configured to signal controls to the second photovoltaic module by relaying commands through the second signal mechanism. The signaling mechanism may also be configured to monitor the second photovoltaic module by receiving telemetries through the second signal mechanism. A transducer is optionally connected to the DC power line and the first transceiver to modulate/demodulate a signal onto/from said power line and a sensor may be connected to the DC power line and the second transceiver to demodulate/modulate the signal from/onto said power line. In an initial mode of operation, an initial signal from the load module is transmitted to the photovoltaic module and an initial code is demodulated by the photovoltaic module. In a subsequent normal mode of operation the initial code is used to validate a control command from the load module. A memory may also be included within the photovoltaic module, the memory preferably adapted to store the initial code.

The foregoing and/or other aspects will become apparent from the following detailed description when considered in conjunction with the accompanying drawing figures.

### BRIEF DESCRIPTION OF THE DRAWINGS

The invention is herein described, by way of example only, with reference to the accompanying drawings, wherein:

FIG. 1a shows a power generation circuit according to an embodiment of the present invention.

FIG. 1b shows further details of a transceiver attached to the output of photovoltaic modules in the power generation circuit shown in FIG. 1a according to an embodiment of the present invention.

FIG. 1c and 1d illustrate respective methods of modulation and demodulation according to aspects of the present invention.

FIG. 1e shows further details of a control and communications unit attached to the load shown in FIG. 1a, according to features of the present invention.

FIG. 2 shows a method according to an embodiment of the present invention.

### DETAILED DESCRIPTION

Reference will now be made in detail to embodiments of the present invention, examples of which are illustrated in the accompanying drawings, wherein like reference numerals refer to the like elements throughout. The embodiments are described below to explain the present invention by referring to the figures.

It should be noted, that although the discussion herein relates primarily to methods in photovoltaic systems, the present invention may, by non-limiting example, alternatively be configured as well using other distributed power systems including (but not limited to) wind turbines, hydro-turbines, fuel cells, storage systems such as battery, super-conducting flywheel, and capacitors, and mechanical devices including conventional and variable speed diesel engines, Stirling engines, gas turbines, and micro-turbines.

It should be noted that although embodiments of the present invention are described in terms of an inverter as a load, the present invention may be applied equally well to other loads including non-grid tied applications such as battery chargers and DC-DC power converters.

Before explaining embodiments of the invention in detail, it is to be understood that the invention is not limited in its application to the details of design and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

The term “pairing or paired” as used herein refers to at least two power generation system components such as an inverter on one side, and on the other side photovoltaic panels and/or electronic modules which are “paired” or associated with each other. “Pairing” establishes an association between an inverter and a particular set of one or more photovoltaic panels and/or electronic modules. The “pairing” between power generation components is typically performed via initial assignment of codes and storage within each power generation component. The “pairing” process may take place at the time of manufacture of power generation system components, during installation of a power generation system, during the operation of the power generation system and/or after an upgrade/modification to the power generation system. The storage of codes typically establishes the electrical connections and future communication protocols of signaling.

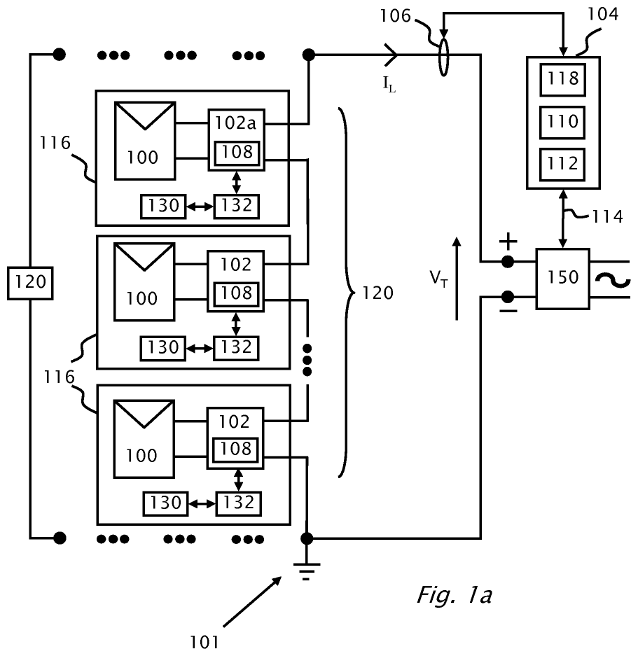

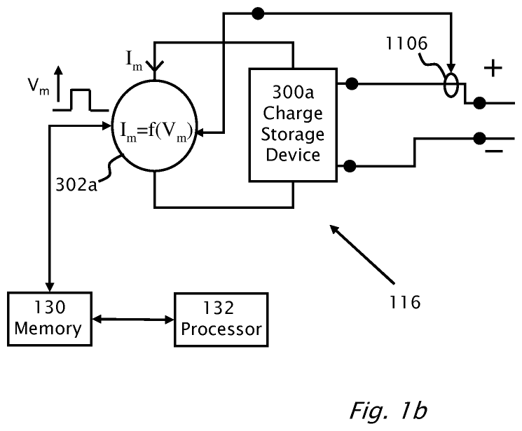

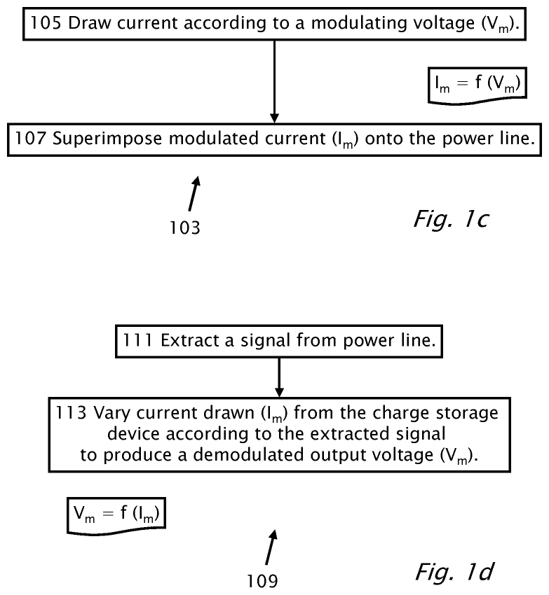

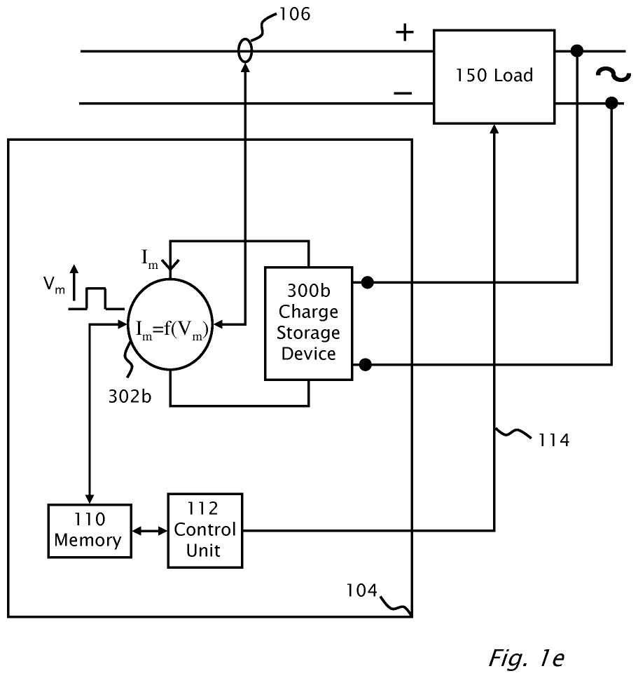

Referring now to the drawings, reference is now made to FIG. 1a which shows a power generation circuit 101 according to an embodiment of the present invention. Two photovoltaic strings 120, by way of example, are connected in parallel to an inverter 150. Details of only one of strings 120 are shown explicitly. In each of strings 120, direct current power sources 116 are serially connected. Each direct current power source 116 includes a photovoltaic panel 100 connected to an electronic module or photovoltaic module 102. Outputs of photovoltaic modules 102 are connected in series to form serial string 120. Photovoltaic modules 102 may be direct current (DC) to DC converters such as a buck circuit, boost circuit, buck/boost or buck+ boost circuit or any other known switching converter topology Attached to photovoltaic modules 102 is a processor 132 which accesses a memory 130. A transceiver 108 is attached to the output of electronic module 102 and to processor 132. According to a feature of the present invention, one of photovoltaic modules 102 referenced 102a is a master electronic module 102a of string 120 and controls and communicates with the other modules, i.e. slave modules 102 via power line communications or wireless link.

Load 150 is typically a direct current (DC) to alternating current (AC) inverter. String 120 attaches across the input of load 150. The output of load 150 is typically attached to an AC grid voltage. Attached to load 150 is inverter module 104. Inverter module 104 contains a memory module 110, transceiver 118 and control unit 112. Inverter module 104 is attached to load 150 with bi-directional connection 114. Transducer 106 is attached to the power connection to load 150 and provides a signal to inverter module 104.

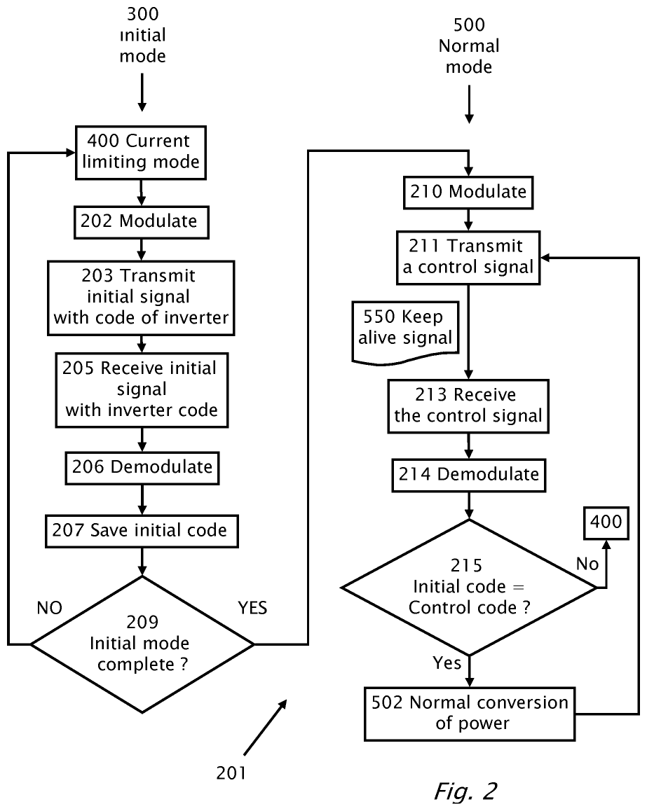

Reference is now made to FIG. 2 which shows a method 201 according to an embodiment of the present invention. Method 201 mitigates the detrimental effects of crosstalk in the communication channel along the power lines connecting photovoltaic modules 102 with inverter module 104. Method 201 illustrates two modes of operation, the first mode of operation is an initial mode 300 and the second mode of operation is a normal mode 500 during which there is normal conversion of power. At the beginning of initial mode 300, current limiting (step 400) typically limits the DC current output of each electronic module 102. The limited DC current output of each module 102, prevents for example, the situation where the entire load 150 current (h) is being supplied by a single string 120 or some strings are not providing any of the load current (h).

An initial code stored in memory 110 modulates (step 202) a variation of voltage or current on the input of load 150 to produce an initial signal. The initial signal is transmitted (step 203) from inverter module 104. Direct electrical variation of current on the input of load 150 may be achieved by using control line 114 to vary the input impedance of load 150 according to a code previously stored in memory 110. The frequency of the transmitted control signal may be between 1 Hz and 100 Hz or may also be at higher frequencies.

The initial signal transmitted (step 203) from inverter module 104 is then received (step 205) by electronic module 102. The initial signal is sensed and a measure of the signal strength of the initial signal may be performed. The measure of the signal strength of the initial signal may be stored in memory 130. The initial signal is demodulated and/or decoded (step 206) by transceiver 108 and the initial code corresponding to inverter module 104 is obtained from the demodulated output voltage. The initial code corresponding to inverter module 104 is stored (step 207) in memory 130.

In order to end initial mode of operation in decision box 209, a control signal is typically modulated (step 210) and transmitted (step 211) from inverter module. The control signal is received (step 213) and demodulated and/or decoded (step 214) by photovoltaic module 102 and a control code is stored. In decision box 215, the control code is compared with the initial code and if the comparison is positive, i.e. the control code is the same as the initial code, then electronic module 102 validates the command as coming from inverter module 104 with which photovoltaic module 102 is paired and not a control signal as crosstalk from another inverter module in the same photovoltaic generation field. In decision box 215, if the initial code positively compares with the control code normal conversion of power (step 502) commences.

An MPP circuit performs maximum peak power tracking (MPPT), in which the current extracted from a photovoltaic panel provides the maximum average power (i.e., if more current is extracted, the average voltage from the panel starts to drop, thus lowering the harvested power). It continuously monitors the current and voltage provided by the panel and uses one of several well-known MPP tracking algorithms to maintain maximum possible power output. Maximum peak power tracking (MPPT) continuously tracks the PV's power output to determine an optimal working point for maximum power.

As an example, of a control signal is a keep alive signal 550. When keep alive signal is encoded with a valid control code then photovoltaic module 102 maintains normal conversion of power. Otherwise, if keep alive signal 550 is not encoded with a valid control signal, such as if the signal received is “pick-up” or cross talk from another inverter in the photovoltaic field then in decision box 215 keep alive signal 550 is not validated and photovoltaic module 102 enters initial mode 400 which is typically a safety or current limited mode of operation until a valid keep alive signal 550 signal is received to enter normal operation 500.

There may be multiple possible frequencies for communication, and during pairing (initial mode 300) the initial signal transmitted to and received by photovoltaic module 102 may specify to photovoltaic module 102 which frequencies to listen to and to transmit on.

Signal strength may be also be used alternatively or in addition to invalidate a control signal or at least set an alert condition. Typically, signal strength variation as measured by photovoltaic module 102 from a transmission from inverter module 104 is not expected to vary more than a threshold ±3 decibel (dB). A variation of signal strength more between the initial transmission (step 203) and the control transmission (step 211) greater than the threshold may set an alarm condition or be used alternatively or in addition to invalidate a control signal in decision box 215 as being sourced by an unpaired inverter module 104.

Reference is now also made to FIG. 1b which illustrates schematically further details of power source 116, according to an embodiment of the present invention. The DC output of power source 116 is connected to a charge storage device 300a. Charge storage device 300a has a direct current (DC) output which supplies power to a modulator/demodulator unit 302a. A transducer/sensor 1106 attached to the output of module 102 connects to modulator/demodulator 302a.

Modulator/demodulator unit 302a has a bi-directional connection to memory 130 and/or processor 132 for storing a (de)modulation voltage Vₘ or a code decoded from an input signal. The DC output of charge storage device 300a may provide processor 132 and memory 130 with DC power. Charge storage device 300a is typically a battery or a capacitor which is charged via the DC output of module 102 during daytime operation of power circuit 101. The charge stored in storage device 300a during daytime may be used at nighttime.

Reference is now made to FIG. 1e which shows further details of inverter module 104 attached to load 150 in power generation circuit 101 according to an embodiment of the present invention. The output of load 150 is connected to an AC grid voltage. The AC grid voltage is connected to charge storage device 300b. Charge storage device 300b is typically a battery or a capacitor which is charged via the rectified grid voltage on the output of load 150 and/or from the DC input to load 150 during daytime operation. Charge storage device 300b has a direct current (DC) output which supplies power to modulator/demodulator unit 302b. Transducer 106, connected at the input of load 150, is connected to modulator/demodulator unit 302b. Modulator/demodulator unit 302b also has a connection to memory 110 or control unit 112. Control unit 112 is attached to memory 110. Control unit 112 is attached to load 150 via control line 114. The DC output of charge storage device 300b may provide control unit 112 and memory 110 with DC power.

Reference is now made to FIG. 1e which shows a method 103 used to operate transceiver 108/118 according to different aspects of the present invention.

The transmission of the control signal from inverter module 104 is preferably performed by transceiver 118 with method 103. The transmission of telemetries by photovoltaic module 102 is by transceiver 108 with method 103. When photovoltaic module 102 sends telemetries, a source identification code identifying the photovoltaic module 102 as the source and a destination identification code identifying inverter module 104 as the destination may be included in the communication signal.

When transceiver 108/118 is operating as a transmitter, modulator 302a/302b causes a modulated signal to be superimposed (step 107) on to the DC power line. Modulator 302a/302b has an input voltage (Vₘ) which causes a current (Iₘ) to be drawn (step 105) from charge storage device 300a/300b which in turn draws current from the output of module 102 and from the input of load 150 respectively. The current drawn from charge storage device 300a/300b is therefore a function of the input voltage i.e. modulating voltage (Vₘ). The superposition (step 107) of the modulated signal on to the DC power line is preferably via transducer 106/1106 or by a direct electrical connection (i.e. via a coupling capacitor) to the DC power line.

According to an exemplary embodiment of the present invention, the transmission of the control signal from inverter module 104 is optionally performed without the use of transducer 106. Instead the modulated control signal is made by altering of the input impedance of load 150 according to a code in memory 110 via control line 114. The variation of the input impedance of load 150 causes the DC input current of load 150 (drawn from modules 102) to vary by virtue of Ohm's law. The drawn current from modules 102 is sensed by transducer 1106 and de-modulated by transceiver 108 in module 102.

Reference is now made to FIG. 1d which shows a method 109 used to operate transceiver 108/118 according to an aspect of the present invention. The reception of telemetries by inverter module 104 is performed by transceiver 118 with method 109. The reception of the control signal from inverter module 104 by photovoltaic modules 102 is performed by transceiver 108 with method 109. When transceiver 108/118 is operating as a receiver a signal present on the DC power line is extracted (step 111) from the DC power line via transducer 106/1106 or by direct electrical connection (i.e. via coupling capacitor). Demodulator 302a/302b de-modulates the sensed signal present on the DC power line. In demodulation, the signal sensed and extracted (step 111) from the DC power line may vary (step 113) the current (Iₘ) drawn from charge storage device 300a/300b which in turn draws current from the output of module 102 and from the input of load 150 respectively to produce a demodulated output voltage Vₘ. The demodulated output voltage (Vₘ) is a function of drawn current Iₘ.

While the invention has been described with respect to a limited number of embodiments, it will be appreciated that many variations, modifications and other applications of the invention may be made.

1. A system comprising:
a photovoltaic (PV) module coupled to a photovoltaic (PV) generator; and
a communication module,
wherein the communication module is configured to send an initial signal to the PV module, and the PV module is configured to:
retrieve an initial code from the initial signal;
pair the PV module to the communication module;
receive a control signal;
retrieve a control code from the control signal;
compare the control code to the initial code;
determine, based on the comparison, that the control signal is valid; and
operate, based on a determination that the control signal is valid, the PV module to enable output power from the PV generator according to a maximum power point tracking algorithm.

2. The system of claim 1, wherein the PV module is configured to exclude, based on the paired PV module and communication module, the PV module from validating commands signaled by devices other than the communication module.

3. The system of claim 1, wherein the initial signal is a wireless signal.

4. The system of claim 1, wherein the initial signal is a signal modulated over a power line coupled to an output of the PV module.

5. The system of claim 1, wherein the initial signal comprises a source identification code identifying the communication module as a source of the initial signal.

6. The system of claim 1, wherein the PV module is configured to determine, based on the comparison, that the control signal is valid by validating, based on the control code matching a source identification code of the initial signal, the control code retrieved from the control signal.

7. The system of claim 1, wherein the control signal comprises a keep-alive signal.

8. The system of claim 1, wherein the PV module is configured to compare the control code to the initial code by comparing a signal strength of the control signal to a signal strength of the initial signal.

9. The system of claim 1, wherein the PV module is configured to output power from the PV generator by converting power, using maximum peak power tracking, from the PV generator to an output of the PV module.

10. The system of claim 1, wherein the communication module is coupled to a load via a control line.

11. The system of claim 1, wherein the communication module is integrated in a direct current (DC)-to-alternating current (AC) converter.

12. A method comprising:
operating a photovoltaic (PV) module in an initial mode;
receiving a control signal from a communication module;
determining whether the communication module is paired to the PV module; and
based on the determining and the control signal, determining whether to operate the PV module in a power production mode, wherein the power production mode comprises enabling transfer of power from an input of the PV module to an output of the PV module according to a maximum power point tracking algorithm.

13. The method of claim 12, wherein the operating the PV module in the initial mode is for a period of time, and wherein the method further comprises, based on a determination that the communication module is not paired to the PV module, operating the PV module in the initial mode for another period of time.

14. The method of claim 12, wherein the power production mode comprises operating a direct current (DC)-to-DC converter to convert power from an input of the PV module to an output of the PV module.

15. A method comprising:
receiving, by a photovoltaic (PV) module coupled to a photovoltaic (PV) generator and from a communication module, an initial signal;
retrieving an initial code from the initial signal;
pairing the PV module to the communication module;
receiving, by the PV module, a control signal;
retrieving a control code from the control signal;
comparing the control code to the initial code;
determining, based on the comparing, that the control signal is invalid; and
operating, based on the determining that the control signal is invalid, the PV module in a safety mode of operation, wherein the safety mode of operation comprises a current limited mode of operation or a voltage limited mode of operation.

16. The method of claim 15, wherein the determining comprises, based on a determination that the comparing is not resulting in a positive comparison, determining that the control signal is invalid.

17. The method of claim 15, wherein the determining comprises setting an alert condition.

18. The method of claim 15, wherein the determining comprises invalidating, based on the control code mismatching a source identification code of the initial signal, the control code retrieved from the control signal.

19. The method of claim 15, further comprising:
excluding, based on the pairing, the PV module from validating commands signaled by devices other than the communication module.

20. The method of claim 15, wherein the receiving the initial signal comprises receiving a wireless signal.

21. The method of claim 15, wherein the receiving the initial signal comprises receiving a signal modulated over a power line coupled to an output of the PV module.

22. The method of claim 15, wherein the receiving the initial signal comprises receiving a source identification code identifying the communication module as a source of the initial signal.

23. The method of claim 15, wherein the control signal comprises a keep-alive signal.

24. The method of claim 15, wherein the comparing the control code to the initial code comprises comparing a signal strength of the control signal to a signal strength of the initial signal.

25. The method of claim 15, wherein the communication module is coupled to a load via a control line.

26. The method of claim 15, wherein the communication module is integrated in a direct current (DC)-to-alternating current (AC) converter.

27. A method comprising:
receiving, by a photovoltaic (PV) module coupled to a photovoltaic (PV) generator and from a communication module, an initial signal;
retrieving an initial code from the initial signal;
pairing the PV module to the communication module;
receiving, by the PV module, a control signal;
retrieving a control code from the control signal;
comparing the control code to the initial code;
determining, based on the comparing, that the control signal is valid; and
enabling, based on the determining that the control signal is valid, the PV module to output power from the PV generator according to maximum power point tracking.

28. An apparatus comprising:
a photovoltaic (PV) generator configured to provide electrical power on an output;
a communications device; and
a processor configured to:
limit the electrical power provided from the output of the PV generator;
receive an initial signal through the communications device;
receive a control signal through the communications device;
validate a control code received in the control signal against an initial code received in the initial signal; and
commence, based on validation of the control code, generation of power on the output of the PV generator according to maximum power point tracking.
